(19) United States
(12) Patent Application Publication
(10) Pub. No.: US 2026/0255496 A1
(43) Pub. Date: Aug. 27, 2026

(54) STRADDLE-MOUNT CONNECTOR REWORK

(71) Applicant: INTERNATIONAL BUSINESS MACHINES CORPORATION, ARMONK, NY (US)

(72) Inventors: Angelina Alexopoulos, Rochester, MN (US); Logan Bistodeau, Rochester, MN (US); Mert Karakas, Rochester, MN (US); Theron Lee Lewis, Rochester, MN (US); Emma Quinn, Rochester, MN (US)

(21) Appl. No.: 19/061,071

(22) Filed: Feb. 24, 2025

(51) Int. Cl. H05K 3/22; H01R 12/70; H01R 12/72; H01R 43/02

(52) U.S. Cl. CPC H05K 3/225; H01R 12/707; H01R 12/721; H01R 43/0263; H05K 2203/0165

(57) ABSTRACT

A method for automated removal of a straddle mount connector within a rework process includes arranging a nozzle system over a straddle mount connector, the straddle mount connecter being affixed to a printed circuit board assembly, and the printed circuit board assembly being situated at a rework station. The method further includes generating a heat flow by the nozzle system in a heat flow area, triggering a release mechanism in the nozzle system in response to a threshold temperature being reached in the heat flow area, releasing a spring-loaded feature of the nozzle system by the triggering the release mechanism, and automatically removing the straddle mount connector from the printed circuit board assembly with the releasing of the spring-loaded feature. Further disclosed is an automated rework system and a nozzle system for an automated rework system configured to perform methods of automated removal of a connector within a rework process.

### BACKGROUND

The present invention relates to straddle-mount connectors, and more particularly to a method and system for removing straddle-mount connectors with automation.

### SUMMARY

In one embodiment, the present invention provides a method for automated removal of a straddle mount connector within a rework process. The method includes arranging a nozzle system over a straddle mount connector, the straddle mount connecter being affixed to a printed circuit board assembly, and the printed circuit board assembly being situated at a rework station. The method further includes generating a heat flow by the nozzle system in a heat flow area, triggering a release mechanism in the nozzle system in response to a threshold temperature being reached in the heat flow area, releasing a spring-loaded feature of the nozzle system by the triggering the release mechanism, and automatically removing the straddle mount connector from the printed circuit board assembly with the releasing of the spring-loaded feature.

In another embodiment, an automated rework system includes a ball grid array rework station column; a nozzle system connected to the ball grid array rework station column; and a rework station. The nozzle system is configured to: be arranged over a straddle mount connector affixed to a printed circuit board assembly situated at the base rework station; generate a heat flow in a heat flow area; trigger a release mechanism in the nozzle system in response to a threshold temperature being reached in the heat flow area; release a spring-loaded feature of the nozzle system by the triggering the release mechanism; and automatically remove the straddle mount connector from the printed circuit board assembly with the releasing of the spring-loaded feature.

In another embodiment, a nozzle system for an automated rework system includes a frame; a release mechanism; a heat flow generator; and a spring loaded feature. The nozzle system is configured to be arranged over a straddle mount connector affixed to a printed circuit board assembly situated at a base rework station. The heat flow generator is configured to generate a heat flow in a heat flow area. The release mechanism is configured to be triggered in response to a threshold temperature being reached in the heat flow area. The spring-loaded feature is configured to be released by the triggering the release mechanism. The nozzle system is configured to automatically remove the straddle mount connector from the printed circuit board assembly with the releasing of the spring-loaded feature.

### BRIEF DESCRIPTION OF THE DRAWINGS

FIG. 1 is straddle mount connector, in accordance with embodiments of the present invention.

FIG. 2 is side cross sectional view of the straddle mount connector of FIG. 1, in accordance with embodiments of the present invention.

FIG. 3 is an automated rework system, in accordance with embodiments of the present invention.

FIG. 4 is a side schematic view of a memory metal solution using an automated rework system, in accordance with embodiments of the present invention.

FIG. 5 is an expanded side schematic view of the memory metal solution of FIG. 4, in accordance with embodiments of the present invention.

FIG. 6 is process flow of the memory metal solution of FIGS. 4-5, in accordance with embodiments of the present invention.

FIG. 7A is a first step of the process flow of FIG. 6, in accordance with embodiments of the present invention.

FIG. 7B is a second step of the process flow of FIG. 6, in accordance with embodiments of the present invention.

FIG. 7C is a third step of the process flow of FIG. 6, in accordance with embodiments of the present invention.

FIG. 7D is a fourth step of the process flow of FIG. 6, in accordance with embodiments of the present invention.

FIG. 8 is a side schematic view of an electronic trigger solution using an automated rework system, in accordance with embodiments of the present invention.

FIG. 9 is an expanded side schematic view of the electronic trigger solution of FIG. 8, in accordance with embodiments of the present invention.

FIG. 10 is process flow of the memory metal solution of FIGS. 8-9, in accordance with embodiments of the present invention.

FIG. 11A is a first step of the process flow of FIG. 10, in accordance with embodiments of the present invention.

FIG. 11B is a second step of the process flow of FIG. 10, in accordance with embodiments of the present invention.

FIG. 11C is a third step of the process flow of FIG. 10, in accordance with embodiments of the present invention.

FIG. 11D is a fourth step of the process flow of FIG. 10, in accordance with embodiments of the present invention.

FIG. 12 is a flowchart of a process for performing straddle mount connector rework using the memory metal solution of FIG. 4-7D, in accordance with embodiments of the present invention.

FIG. 13 is flowchart of a process for performing straddle mount connector rework using the electronic trigger solution of FIG. 8-11D, in accordance with embodiments of the present invention.

### DETAILED DESCRIPTION

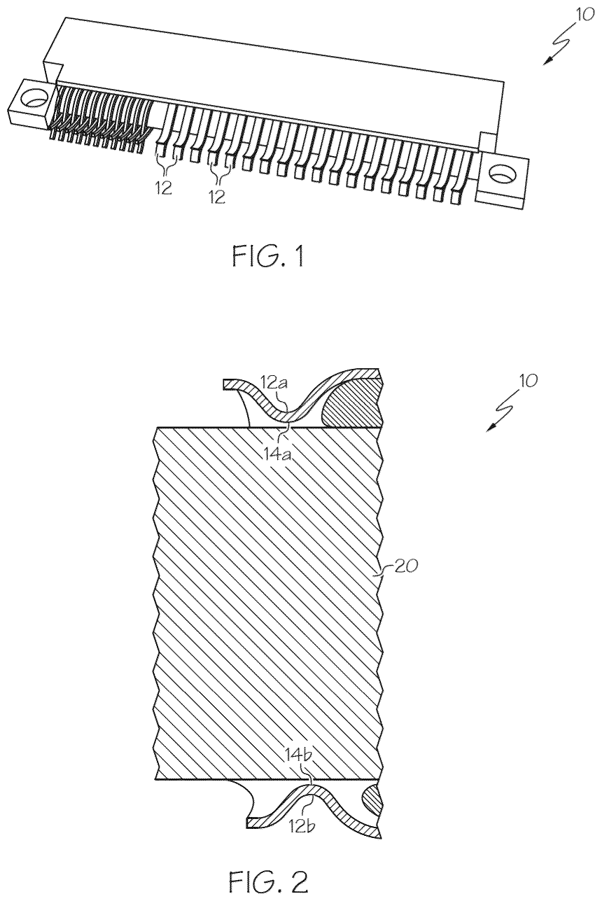

With reference now to FIG. 1, a straddle mount connector 10 is shown in accordance with embodiments of the present invention. Straddle mount connectors (SMCs), such as the straddle mount connector 10 shown, are becoming more common in the printed circuit board (PCBA) industry. SMCs, such as the straddle mount connector 10, include surface mount technology (SMT) leads 12 to be soldered on both sides of the printed circuit board (PCB). FIG. 2 is side cross-sectional view of the straddle mount connector 10 of FIG. 1, in accordance with embodiments of the present invention. As shown, the straddle mount connector 10 includes the leads 12a, 12b on each side of a PCB 20 soldered to create respective solder joints 14a, 14b.

Unlike traditional connectors that are soldered onto the surface of a circuit board, the straddle mount connector 10 straddles the edge of the PCB 20 as shown in FIG. 2. This means the straddle mount connector 10 mounts over the edge, with contact points on both sides of the PCB 20. The design of the straddle mount connector 10 may allow for dual-sided connectivity, which creates more compact designs or complex routing signals by allowing components or connectors to be attached to both sides of the PCB 20.

SMCs, such as the straddle mount connector 10, may be configured to provide a secure connection between the PCB and external components or devices. This can be essential in applications where vibration or movement might otherwise cause traditional connectors to come loose. SMCs may have applications in various industries where reliability and compactness are crucial design considerations, such as, automotive, aerospace, telecommunications, and consumer electronics. SMCs are often used in high-density applications where space-saving is important.

Rework of SMCs is challenging due to removing and/or reflowing the solder enough to release the solder joints. A typical process is labor intensive with soldering irons. Removal is generally manual with these rework processes, which make the PCB more susceptible to delamination. Specifically, industry standard rework processes include various manual steps including assessment, preparing of tools and materials, de-soldering, removal, cleaning of the area, prepare a new connector, alignment, soldering, inspecting and testing, and cleaning up and documenting the process for future reference.

The present disclosure presents a novel method for the removal of straddle mount connectors, such as the straddle mount connector 10, using automation. In one proposed method, a memory metal trigger is deployed. In another proposed method, a temperature and/or electrical reading mechanism is utilized to trigger release.

Thus, the present disclosure contemplates the automated removal of the connector within the rework nozzle system without using a dedicated pallet/fixture system. Specifically, the present disclosure provides a rework process which includes a Hot Gas Rework Station, a nozzle system that engages the Hot Gas Rework station and uses mechanisms to pull off the connector system. The nozzle system is contemplated to be designed to engage the specific machine that would be doing the rework process. The removal system as contemplated herein may not need a dedicated pallet/fixture system. The contemplated nozzle system uses a clamping system that engages the connector housing and has a spring plate that, when released, pulls on the connector. Further, systems described herein heats both sides of the SMC connector simultaneously.

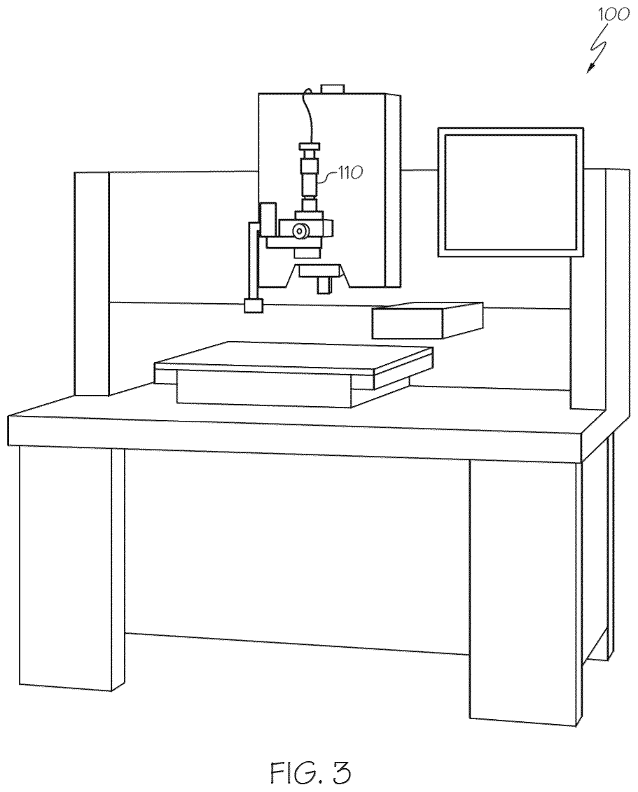

FIG. 3 is an automated rework system 100, in accordance with embodiments of the present invention. The automated rework system 100 includes a rework nozzle 110 configured to attach to a BGA rework station. The rework nozzle 110 may be configured to simultaneously apply heat to both sides of the SMT contact regions. The rework nozzle 110 may be configured to align from the side of the connector and isolates heat to the SMT regions. The automated rework system 100 may further include a rework pallet system (shown herein below) with a biasing element (e.g., a mechanical clamp) which engages the connector.

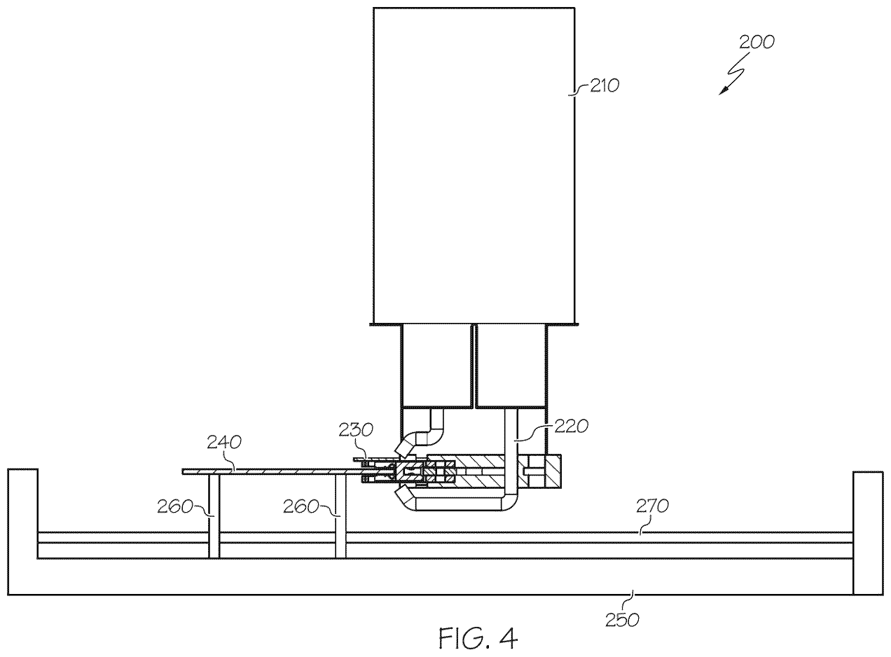

FIG. 4 is a side schematic view of a memory metal solution using an automated rework system 200, in accordance with embodiments of the present invention. The automated rework system 200 includes a BGA rework station column 210. A nozzle system 220 is attached to the BGA rework station column 210. As shown, the nozzle system 220 is engaged with a SMC 230 which is connected to a PCBA 240. The automated rework system 200 further is shown to include a base 250 having supports 260. The automated rework system 200 further includes a backside heating source 270 configured for IR or convection airflow.

The automated rework system 200 is configured to deploy memory shape metals as a solution for removing the SMC 230 from the PCBA 240. Memory shape metals deployed in the memory metal solution described herein may also be known as: Shape-Memory Alloy, Smart Metal, Memory Metal, Muscle Wire, Smart Alloy. Memory shape metals are defined as an alloy metal that “remembers” its original shape and that, when deformed, returns to its pre-deformed shape when heat energy or magnetic energy is applied to it (depending on the alloy). Ferromagnetic shape-memory metals are the group of alloys that react to magnetic fields. For example, common alloy groups are the copper-aluminum-nickel, and nickel-titanium. A memory metal alloy has an original crystal structure then metal is deformed and causes a different crystal structure to form. Depending on the alloy, heat energy or magnetic energy is applied and the metal returns to its original crystal structure. Unlike most crystal structure changes in metals, this crystal structure change does not require diffusion. Other example memory shape metals may be created using zinc, copper, gold and iron. Although iron-based and copper-based memory shape metals, such as Fe—Mn—Si, Cu—Zn—Al and Cu—Al—Ni, are commercially available. Moreover, NiTi-based memory shape metals may also be preferable due to their stability and practicability as well as their superior thermo-mechanical performance. Memory shape metals may exist in two different phases, with three different crystal structures (i.e. twinned martensite, detwinned martensite, and austenite).

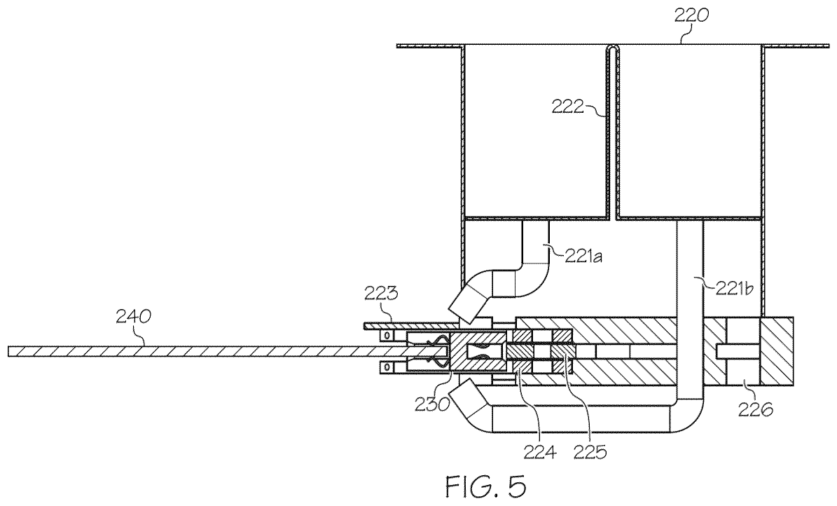

FIG. 5 is an expanded side schematic view of the nozzle system 220 of the memory metal solution of FIG. 4, in accordance with embodiments of the present invention. In particular, the nozzle system 220 is shown holding the SMC 230 which is attached to the PCBA 240. The nozzle system 220 includes an upper hot air nozzle duct 221a configured to provide hot air to the upper portion of the SMC 230, and a lower hot air nozzle duct 221b configured to provide hot air to the lower portion of the SMC 230. Each of the upper and lower hot air nozzle ducts 221a, 221b are operably connected to an air diffuser 222. Release mechanisms 223 are attached to the nozzle system 220 and may be configured to release when the memory metal is heated. Attached to a frame 226 of the nozzle system 220 are SMC clamps 224 and a spring plate 225.

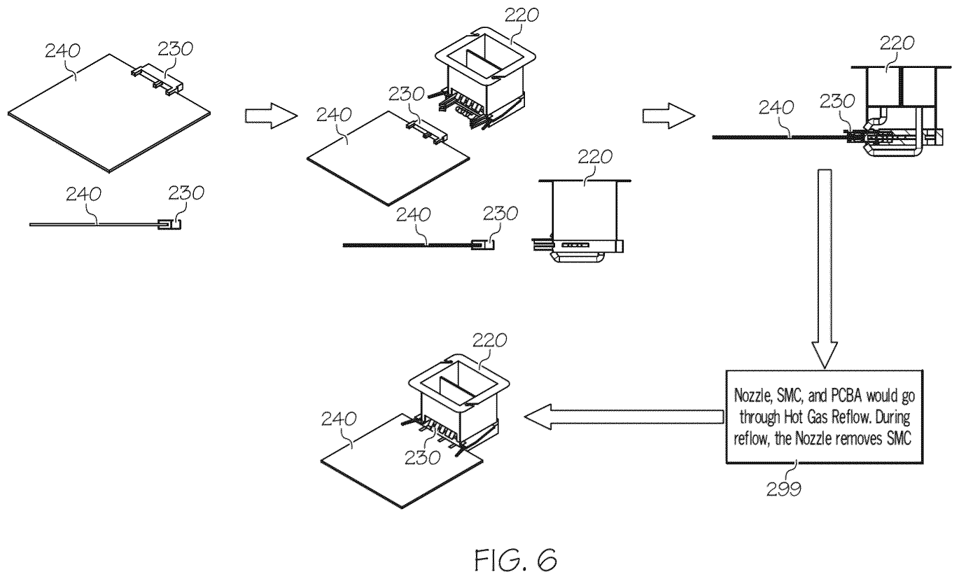

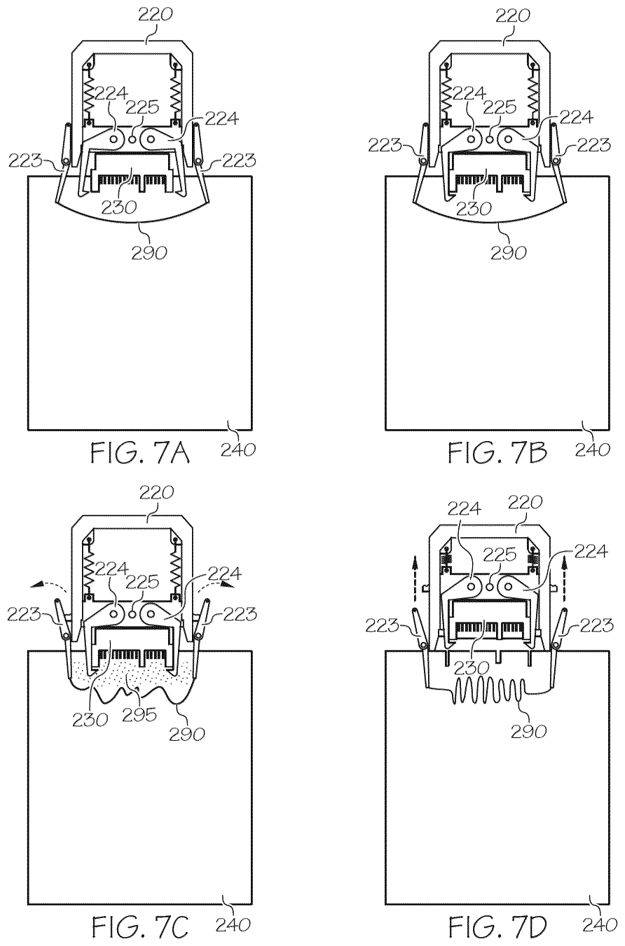

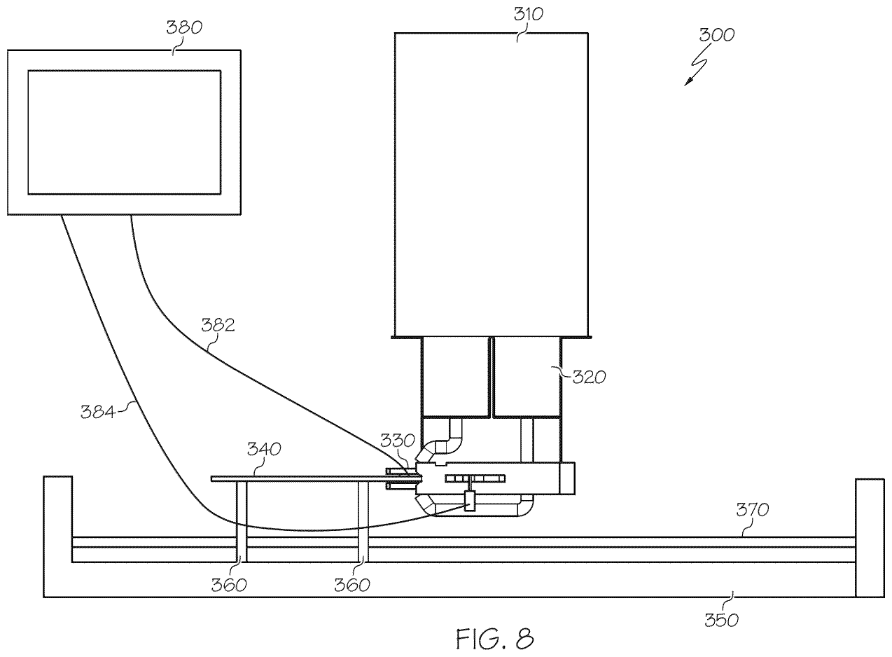

FIG. 6 is process flow of the memory metal solution of FIGS. 4-5, in accordance with embodiments of the present invention. In particular, FIG. 6 shows perspective and side views of the PCBA 240 with the attached SMC 230 that requires rework. At a second step, a nozzle system 220 of an automated rework system (such as automated rework system 200) is brought into proximity of the PCBA 240 and the SMC 230. At a third step, the nozzle system 220 engages with the SMC 230. At a step 299, the nozzle system 220, SMC 230 and PCBA 240 would go through a hot gas reflow system using the hot air nozzle ducts 221a, 221b of the nozzle system 220. During reflow, the nozzle system 220 removes the SMC 230. This removal process is then shown in FIG. 7A-7D.

FIG. 7A is a first step of the process flow of FIG. 6, in accordance with embodiments of the present invention. As shown, the nozzle system 220 is slid onto the PCBA 240 proximate the SMC 230. A memory shape metal 290 is shown affixed to an SMT side of the connector system in-line with the heat flow of the nozzle system 220. The spring plate 225 is shown as a spring-loaded feature of the nozzle system 220 which is enabled and engaging the connector with the memory shape metal 290. In other words, because the memory shape metal is in an expanded state, the spring plate 225 remains in place with the springs under expansion tension.

FIG. 7B is a second step of the process flow of FIG. 6, in accordance with embodiments of the present invention. As shown in this second step, the SMC clamps 224 secure the nozzle system 220 onto the SMC 230. At this second step, the nozzle system 220 is becomes attached to the PCBA 240, and more particularly the SMC 230.

FIG. 7C is a third step of the process flow of FIG. 6, in accordance with embodiments of the present invention. As shown, the nozzle system 220 activates the air diffuser 222 and/or the upper and lower hot air nozzle ducts 221a, 221b in order to create a reflow heating zone 295. This heat application causes the memory shape metal 290 to begin to heat, contracting the memory shape metal 290 to its pre-deformed shape. This begins to cause the release mechanisms 223 to be pulled by the contracting memory shape metal 290.

FIG. 7D is a fourth step of the process flow of FIG. 6, in accordance with embodiments of the present invention. At this step, the memory shape metal 290 reaches full contraction. This fully releases the actuators 223, causing the actuators 223 to disengage with a spring-loaded mechanism of the spring plate 225. Because the springs are under expansion tension prior to this release, the disengagement of the actuators 223 causes the springs to return to their equilibrium state, which pulls the spring plate 225 away from the PCBA 240 and the SMC 230 is pulled off the PCBA 240 via the spring plate 225 and the SMC clamps 224.

Thus, in the embodiment shown in FIG. 4-7D, the memory shape metal 290 is used to release the actuators 223 that engage the spring plate 225. The memory shape metal 290 is placed or positioned in the hot gas airflow. When the memory shape metal 290 reaches its transition temperature, the memory shape metal 290 shrinks, pulling the levered actuator mechanism 223 that releases a spring plate 225 to remove the SMC 230.

The memory shape metal 290 may have a memory transition point that may be a minimum of 5° C. higher than the melting point of the solder used to attach the SMC 230. The memory shape metal 290 may include an original shape (shown in FIG. 7D) which may include simple and complex shapes. The particular alloy of the memory shape metal 290 may be determined, as well as the particular placement and proper thermal profiling.

Thus, in various embodiments, methods may include preparing the memory shape metal 290 by setting a shape of the material and the particular higher temperature than the melting point of the solder used to attach the SMC 230. Methods may further include, at the PCBA rework area, placing the PCBA 240 into the automated rework system 200 with proper supports. Methods may include arranging the nozzle system 220 over the SMC 230.

Methods may further include enabling spring-loaded features which engage the SMC 230, such as the spring plate 225 of the nozzle system 220, with the memory shape metal 290 and/or wire. Methods may include placing the memory shape metal 290 on the SMT side of the SMC 230 and further placing the memory shape metal 290 in the path of the heat flow of the nozzle system 220.

Methods may then include running pre-heat and reflow from the nozzle system 220. Once the SMT joints reach proper reflow/melting point, methods include the memory shape metal 290 being caused to shape and release the spring mechanism of the spring plate 225 in the nozzle system 220. Methods may further include the nozzle system 220 pushing the SMC 230 away from the PCBA 240, which fully removes the SMC 230 from the PCBA 240.

In various embodiments, the metal chosen for the memory shape metal 290 may be an alloy that reacts at roughly 217° C. when using SAC solder. If a low melting point material such as SnBi, is used, then 140° C. memory metal material may be used, for example. Once the SMC 230 is removed, an operator site dresses the lands on the PCB, then applies fresh solder paste so that a connector (either the same or a different SMC 230) may be placed back on the PCBA 240. Once this occurs, the specialized nozzle system 220 may be reapplied to the automated rework system 200, whereby reflow may be run to melt the solder paste and reform the solder joints to the new connector system.

FIG. 8 is a side schematic view of an electronic trigger solution using an automated rework system 300, in accordance with embodiments of the present invention. The automated rework system 300 includes a BGA rework station column 310. A nozzle system 320 is attached to the BGA rework station column 310. As shown, the nozzle system 320 is engaged with a SMC 330 which is connected to a PCBA 340. The automated rework system 300 further is shown to include a base 350 having supports 360. The automated rework system 300 further includes a backside heating source 370 configured for IR or convection airflow. The various components 310, 320, 330, 340, 350, 360, 370 of the automated rework system 300 may be the same or similar to the automated rework system 200 described herein above. Further, the automated rework system 300 includes a computer system 380. A thermocouple 382 is attached to and extends between the computer system 380 and a heat flow area. Further, the automated rework system 300 includes at least one electronic trigger wire 384 extending between the computer system 380 and a release mechanism configured to release a spring plate of the nozzle system 320 (shown herein below).

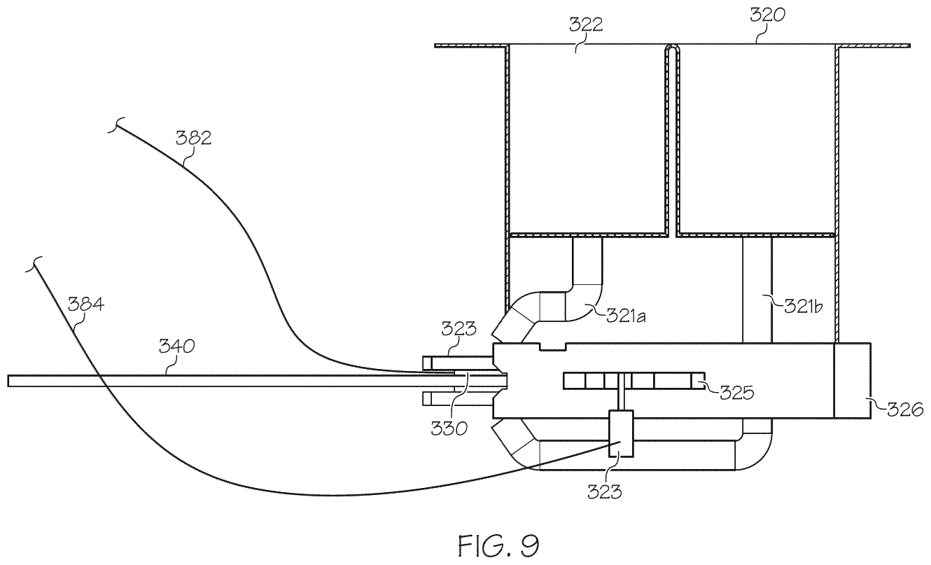

FIG. 9 is an expanded side schematic view of the nozzle system 320 of FIG. 8, in accordance with embodiments of the present invention. In particular, the nozzle system 320 is shown holding the SMC 330 which is attached to the PCBA 340. The nozzle system 320 includes an upper hot air nozzle duct 321a configured to provide hot air to the upper portion of the SMC 330, and a lower hot air nozzle duct 321b configured to provide hot air to the lower portion of the SMC 330. Each of the upper and lower hot air nozzle ducts 321a, 321b are operably connected to an air diffuser 322. Release mechanisms 323 are attached to the nozzle system 320 and may be configured to release via the electronic trigger wires 384 when the computer system 380 detects, via the thermocouple 382, that a threshold temperature has been reached. Attached to a frame 326 of the nozzle system 320 are SMC clamps 324 and a spring plate 325.

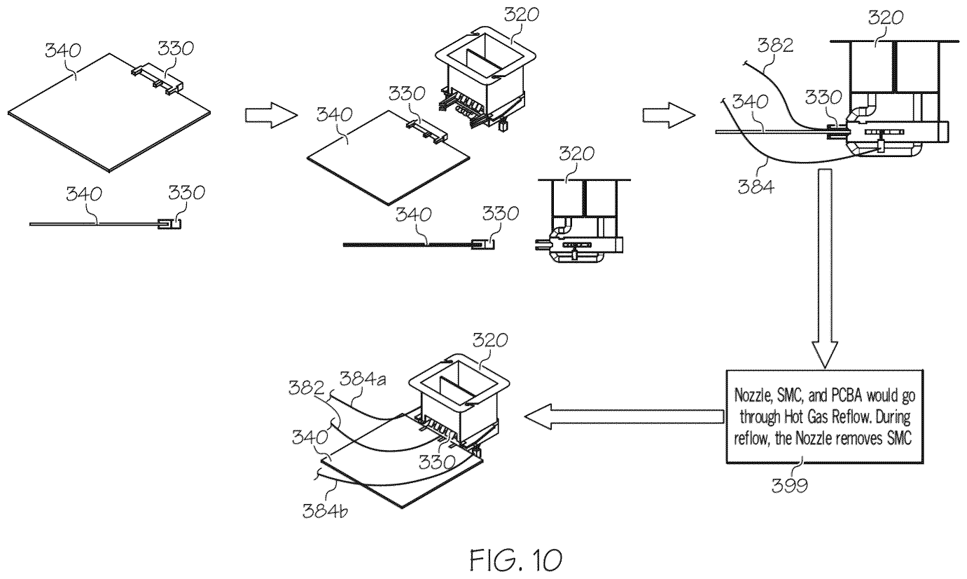

FIG. 10 is process flow of the memory metal solution of FIGS. 8-9, in accordance with embodiments of the present invention. In particular, FIG. 10 shows perspective and side views of the PCBA 340 with the attached SMC 330 that requires rework. At a second step, a nozzle system 320 of an automated rework system (such as automated rework system 300) is brought into proximity of the PCBA 340 and the SMC 330. At a third step, the nozzle system 320 engages with the SMC 330. At this stage, the thermocouple 382 and electronic trigger wires 384 may be attached to the computer system 380 and their respective locations (i.e. a heat flow area in the case of the thermocouple 382 and the release mechanisms 323 in the case of the electronic trigger wires). At a step 399, the nozzle system 320, SMC 330 and PCBA 340 would go through a hot gas reflow system using the hot air nozzle ducts 321a, 321b of the nozzle system 320. During reflow, the nozzle system 320 removes the SMC 330. This removal process is then shown in FIG. 7A-7D.

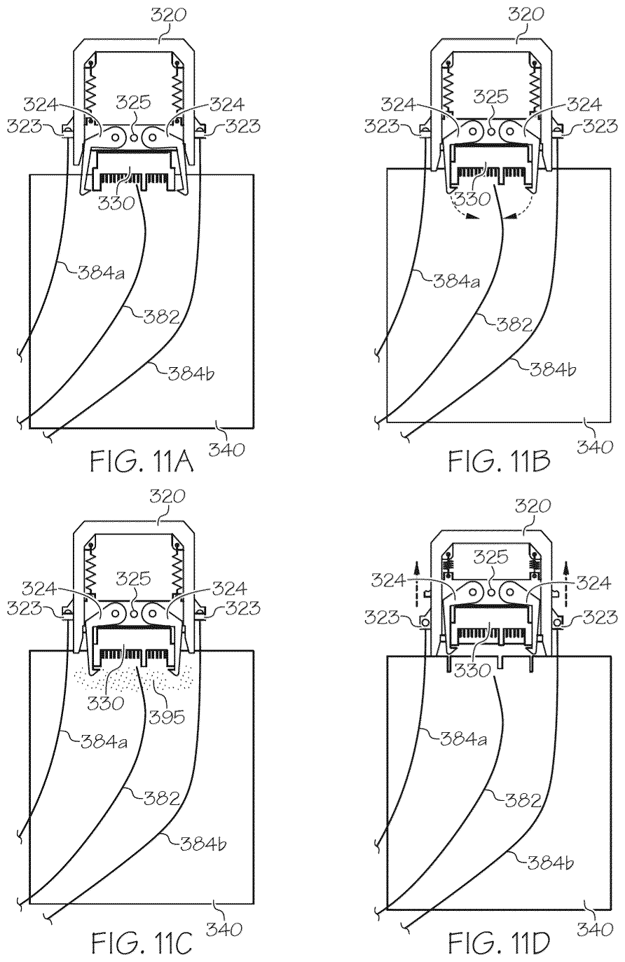

FIG. 11A is a first step of the process flow of FIG. 10, in accordance with embodiments of the present invention. As shown, the nozzle system 320 is slid onto the PCBA 340 proximate the SMC 330. The thermocouple 382 is placed in an area in line with the heat flow of the nozzle system 320, and more particularly, the hot air nozzle ducts 321a, 321b. Similarly, electronic trigger wires 384 are connected to release mechanisms 323 of the nozzle system 320. The spring plate 325 is shown as a spring-loaded feature of the nozzle system 320 which is enabled and loaded and maintained in the loaded state by the release mechanisms 323 which are connected to the electronic trigger wires 384.

FIG. 11B is a second step of the process flow of FIG. 10, in accordance with embodiments of the present invention. As shown in this second step, the SMC clamps 324 secure the nozzle system 320 onto the SMC 330. At this second step, the nozzle system 320 is becomes attached to the PCBA 340, and more particularly the SMC 330.

FIG. 11C is a third step of the process flow of FIG. 10, in accordance with embodiments of the present invention. As shown, the nozzle system 320 activates the air diffuser 322 and/or the upper and lower hot air nozzle ducts 321a, 321b in order to create a reflow heating zone 395. The thermocouple 382 tracks the temperature in the heating zone 395 and feeds this information to the computer system 380. When a temperature reaches a threshold which is set above a melting point of the solder joints of the SMC 330. This sends an electronic signal to the computer system 380 which then sends an electronic signal through the electronic trigger wires 384 to the release mechanisms 323. This causes the release mechanisms 223 to release the spring mechanism.

FIG. 11D is a fourth step of the process flow of FIG. 10, in accordance with embodiments of the present invention. At this step, the release has occurred because the electronic trigger is released. This fully releases the release mechanism 323, causing the release mechanism 323 to disengage with a spring-loaded mechanism of the spring plate 325. Because the springs are under expansion tension prior to this release, the disengagement of the release mechanism 323 causes the springs to return to their equilibrium state, which pulls the spring plate 325 away from the PCBA 340 and the SMC 330 is pulled off the PCBA 340 via the spring plate 325 and the SMC clamps 324.

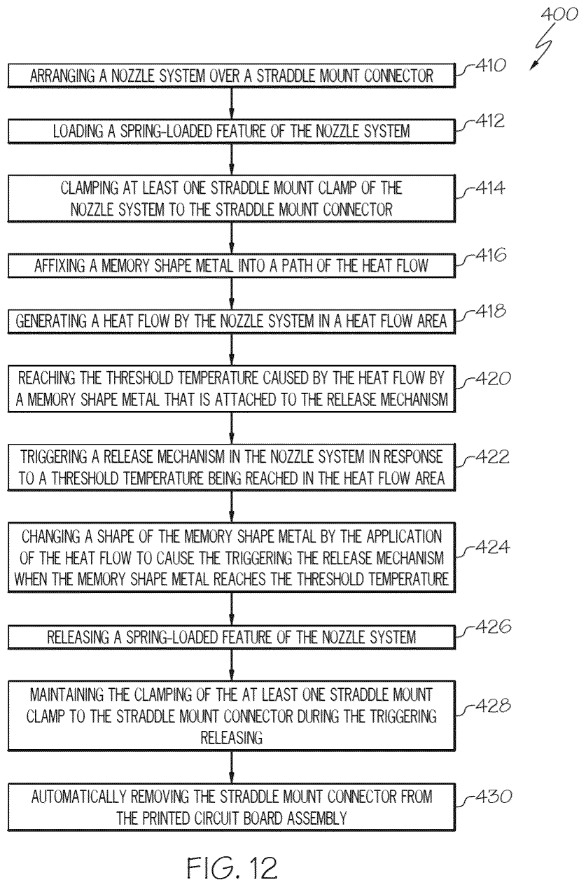

FIG. 12 is a flowchart of a process 400 for performing straddle mount connector rework using the memory metal solution of FIG. 4-7D, in accordance with embodiments of the present invention. The process 400 includes a step 410 of arranging a nozzle system over a straddle mount connector. The process 400 includes a step 412 of loading a spring-loaded feature of the nozzle system. The process 400 includes a step 414 of clamping at least one straddle mount clamp of the nozzle system to the straddle mount connector. The process 400 includes a step 416 of affixing a memory shape metal into a path of the heat flow. The process 400 includes a step 418 of generating a heat flow by the nozzle system in a heat flow area. Further, the process 400 includes a step 420 of reaching the threshold temperature caused by the heat flow by a memory shape metal that is attached to the release mechanism. The process 400 includes a step 422 of triggering a release mechanism in the nozzle system in response to a threshold temperature being reached in the heat flow area. Still further, the process 400 includes a step 424 of changing a shape of the memory shape metal by the application of the heat flow to cause the triggering the release mechanism when the memory shape metal reaches the threshold temperature. The process 400 includes a step 426 of releasing a spring-loaded feature of the nozzle system. Moreover, the process 400 includes a step 428 of maintaining the clamping of the at least one straddle mount clamp to the straddle mount connector during the triggering releasing and a step 430 of automatically removing the straddle mount connector from the printed circuit board assembly.

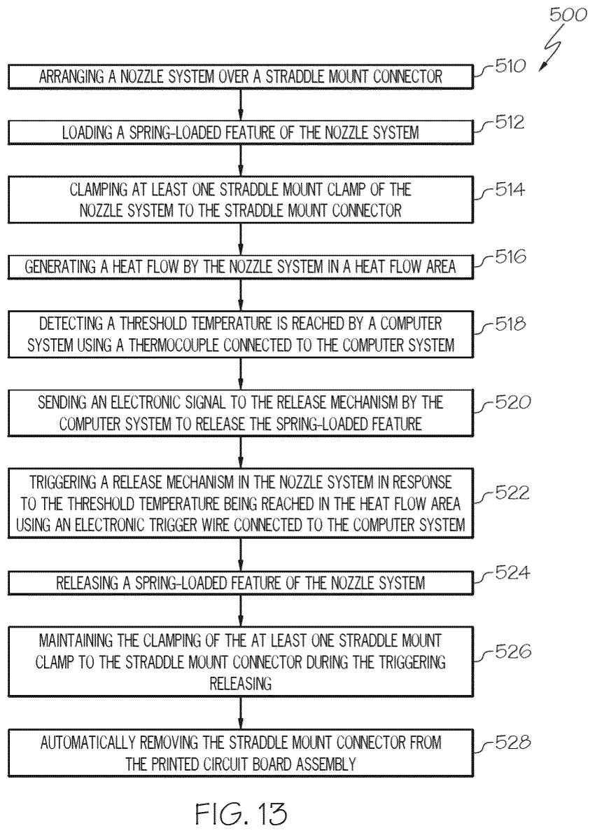

FIG. 13 is flowchart of a process 500 for performing straddle mount connector rework using the electronic trigger solution of FIG. 8-11D, in accordance with embodiments of the present invention. The process 500 includes a step 510 of arranging a nozzle system over a straddle mount connector. The process 500 includes a step 512 of loading a spring-loaded feature of the nozzle system. The process 500 includes a step 514 of clamping at least one straddle mount clamp of the nozzle system to the straddle mount connector. The process 500 includes a step 516 of generating a heat flow by the nozzle system in a heat flow area. The process 500 includes a step 518 of detecting a threshold temperature is reached by a computer system using a thermocouple connected to the computer system. Further, the process 500 includes a step 520 of sending an electronic signal to the release mechanism by the computer system to release the spring-loaded feature. The process 500 still further includes a step 522 of triggering a release mechanism in the nozzle system in response to the threshold temperature being reached in the heat flow area using an electronic trigger wire connected to the computer system. Moreover, the process 500 includes a step 524 of releasing a spring-loaded feature of the nozzle system. The process 500 includes a step 526 of maintaining the clamping of the at least one straddle mount clamp to the straddle mount connector during the triggering releasing and a step 528 of automatically removing the straddle mount connector from the printed circuit board assembly.

Once the connector is removed, in accordance with any of the embodiments described herein above including the processes 400, 500, the operator may then work on the PCBA to undergo site dress on each side and apply fresh solder paste. Next, the SMC may be placed back on the PCBA. Then, the nozzle system may be arranged over the connector system on the BGA rework station and reflow may be run to melt the solder paste and reform the solder joints to the new connector system.

The descriptions of the various embodiments of the present invention have been presented herein for purposes of illustration but are not intended to be exhaustive or limited to the embodiments disclosed. Many modifications and variations will be apparent to those or ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for automated removal of a straddle mount connector within a rework process, comprising:
arranging a nozzle system over a straddle mount connector, the straddle mount connecter being affixed to a printed circuit board assembly, and the printed circuit board assembly being situated at a rework station;
generating a heat flow by the nozzle system in a heat flow area;
triggering a release mechanism in the nozzle system in response to a threshold temperature being reached in the heat flow area;
releasing a spring-loaded feature of the nozzle system by the triggering the release mechanism; and
automatically removing the straddle mount connector from the printed circuit board assembly with the releasing of the spring-loaded feature.

2. The method of claim 1, wherein the threshold temperature is greater than a melting point of solder used to attach the straddle mount connector to the printed circuit board assembly.

3. The method of claim 1, further comprising loading the spring-loaded feature of the nozzle system and maintaining the spring-loaded feature in the loaded state prior to the triggering and releasing.

4. The method of claim 3, wherein the nozzle system further includes a spring plate having the spring-loaded feature and at least one straddle mount connector clamp, the method further including:
clamping the at least one straddle mount clamp of the nozzle system to the straddle mount connector.

5. The method of claim 4, further comprising maintaining the clamping of the at least one straddle mount clamp of the nozzle system to the straddle mount connector during the triggering the release mechanism and releasing the spring-loaded feature.

6. The method of claim 1, wherein the triggering the release mechanism includes reaching the threshold temperature caused by the heat flow by a memory shape metal that is attached to the release mechanism.

7. The method of claim 6, further comprising affixing the memory shape metal into a path of the heat flow.

8. The method of claim 7, further comprising changing a shape of the memory shape metal by the application of the heat flow to cause the triggering the release mechanism when the memory shape metal reaches the threshold temperature.

9. The method of claim 1, wherein the triggering of the release mechanism includes detecting the threshold temperature is reached by a computer system and sending an electronic signal to the release mechanism by the computer system to release the spring-loaded feature.

10. The method of claim 9, wherein the detecting the threshold temperature includes using a thermocouple connected to the computer system and wherein the triggering of the release mechanism includes using at least one electronic trigger wire connected to the computer system.

11. An automated rework system comprising:
a ball grid array rework station column;
a nozzle system connected to the ball grid array rework station column; and
a rework station,
wherein the nozzle system is configured to:
be arranged over a straddle mount connector affixed to a printed circuit board assembly situated at the base rework station;
generate a heat flow in a heat flow area;
trigger a release mechanism in the nozzle system in response to a threshold temperature being reached in the heat flow area;
release a spring-loaded feature of the nozzle system by the triggering the release mechanism; and
automatically remove the straddle mount connector from the printed circuit board assembly with the releasing of the spring-loaded feature.

12. The automated rework system of claim 11, wherein the threshold temperature is greater than a melting point of solder used to attach the straddle mount connector to the printed circuit board assembly.

13. The automated rework system of claim 11, wherein the nozzle system is further configured to maintain the spring-loaded feature in a loaded state prior to the triggering and releasing.

14. The automated rework system of claim 13, wherein the nozzle system further includes a spring plate having the spring-loaded feature and at least one straddle mount connector clamp, wherein the at least one straddle mount clamp of the nozzle system is configured to clamp to the straddle mount connector.

15. The automated rework system of claim 14, wherein the nozzle system is further configured to maintain clamping of the at least one straddle mount clamp to the straddle mount connector during triggering the release mechanism and releasing the spring-loaded feature.

16. The automated rework system of claim 11, wherein a memory shape metal is attached to the release mechanism, wherein the memory shape metal is located in a path of the heat flow.

17. The automated rework system of claim 16, wherein changing a shape of the memory shape metal by the application of the heat flow is configured to cause the triggering the release mechanism when the memory shape metal reaches the threshold temperature.

18. The automated rework system of claim 1, further comprising a computer system configured to detect the threshold temperature is reached and send an electronic signal to the release mechanism to release the spring-loaded feature.

19. The automated rework system of claim 18, further comprising a thermocouple connected to the computer system and at least one trigger wire connected to the computer system, wherein the thermocouple is configured to detect the threshold temperature and wherein the at least one trigger wire is configured to trigger of the release mechanism.

20. A nozzle system for an automated rework system comprising:
a frame;
a release mechanism;
a heat flow generator; and
a spring loaded feature,
wherein the nozzle system is configured to be arranged over a straddle mount connector affixed to a printed circuit board assembly situated at a base rework station;
wherein the heat flow generator is configured to generate a heat flow in a heat flow area;
wherein the release mechanism is configured to be triggered in response to a threshold temperature being reached in the heat flow area;
wherein the spring-loaded feature is configured to be released by the triggering the release mechanism; and
wherein the nozzle system is configured to automatically remove the straddle mount connector from the printed circuit board assembly with the releasing of the spring-loaded feature.
